(19) United States
(12) Patent Application Publication
(10) Pub. No.: US 2020/0067537 A1
(43) Pub. Date: Feb. 27, 2020

(54) POLAR CHANNEL CODING METHOD, DEVICE, AND COMMUNICATIONS SYSTEM

(71) Applicant: HUAWEI TECHNOLOGIES CO., LTD., SHENZHEN (CN)

(72) Inventors: Wenqi FAN, Shanghai (CN); Bin LI, Shenzhen (CN); Hui SHEN, Shenzhen (CN); Jiaji ZHANG, Shanghai (CN); Jingning ZHU, Shanghai (CN)

(21) Appl. No.: 16/671,718

(22) Filed: Nov. 1, 2019

Related U.S. Application Data
(63) Continuation of application No. PCT/CN2018/084783, filed on Apr. 27, 2018.

(30) Foreign Application Priority Data
May 2, 2017 (CN) 201710301119.6

(51) Int. Cl. H03M 13/35; H03M 13/13

(52) U.S. Cl. CPC H03M 13/353; H04B 1/06; H03M 13/13

(57) ABSTRACT

Embodiments of the disclosure provide a polar channel coding method, a device, and a system. The method includes: obtaining, by a sending apparatus, a target coding scheme, where the target coding scheme includes a mother code length N and a quantity K of information bits, N is an integral power of 2, both N and K are positive integers, and N>K; selecting, by the sending apparatus, a target coding table from a plurality of candidate coding tables based on the target coding scheme, where the plurality of candidate coding tables are pre-stored in the sending apparatus; and coding, by the sending apparatus, the K information bits based on the target coding table to obtain a target coding sequence. Embodiments of the disclosure can reduce complexity of polar channel coding.

### CROSS-REFERENCE TO RELATED APPLICATIONS

This application is a continuation of International Application No. PCT/CN2018/084783, filed on Apr. 27, 2018, which claims priority to Chinese Patent Application No. 201710301119.6, filed on May 2, 2017, the disclosures of which are incorporated herein by reference in their entireties.

### TECHNICAL FIELD

The present application relates to the communications field, and in particular, to a polar channel coding method, a device, and a communications system.

### BACKGROUND

As the first channel coding technology that is theoretically proved to be capable of achieving the Shannon capacity, polar coding attracts wide attention. A principle of a polar coding technology is as follows: Channel combination and channel splitting are performed on a group of symmetric binary-input, discrete, memory-less channels, to enable channel capacities of some channels to tend to be 1 (that is, high reliability channels), and enable channel capacities of the other channels tend to be 0 (that is, low reliability channels). Therefore, a channel whose channel capacity tends to be 1 is used to transmit an information bit that carries useful information, and a channel whose channel capacity tends to be 0 is used to transmit a fixed bit that carries redundant information. Currently, the polar coding defeats the Turbo Code 2.0 and the low-density parity-check (LDPC) coding, and becomes a coding scheme for a 5G control channel enhanced mobile broadband (eMBB) scenario.

However, complexity of the polar coding is relatively high currently. Higher coding complexity results in a longer time required for coding, and higher coding complexity imposes a higher requirement on performance of a hardware system. Consequently, application of the polar coding in an ultra reliable and low latency communications (URLLC) scenario and a massive machine type communications (mMTC) scenario is limited.

### SUMMARY

Embodiments of this application provide a polar channel coding method, a device, and a communications system, to reduce complexity of polar channel coding.

According to a first aspect, a polar channel coding method is provided, including:

selecting, by a sending apparatus, a target coding scheme from a plurality of candidate coding schemes, where the target coding scheme is used to indicate a quantity K of information bits and a mother code length N that are used during coding, N is an integral power of 2, both N and K are positive integers, and N>K;

selecting, by the sending apparatus, a target coding table from a plurality of candidate coding tables based on the target coding scheme, where the plurality of candidate coding tables are pre-stored in the sending apparatus; and

coding, by the sending apparatus, the K information bits based on the target coding table to obtain a target coding sequence.

In some embodiments, the target coding table may have the following three specific implementations.

In one embodiment, the target coding table is used to store a target matrix. The target matrix may be implemented in the following two manners:

In one embodiment, the target matrix may be a generation matrix. The generation matrix is an N×N matrix obtained through calculation based on G_{N}=F^{⊗n} where G_{N} is the generation matrix, F^{⊗n} is F raised to a Kronecker power, and F^{⊗n}=F⊗F^{⊗(n-1)}.

A beneficial effect of the first manner is as follows: Because the target coding table stores the generation matrix, when calculating the target coding sequence, the sending apparatus can obtain the generation matrix by simply querying the target coding table, and does not need to calculate the generation matrix in real time, thereby reducing complexity of polar channel coding.

In another embodiment, the target matrix may be a simplified matrix. The simplified matrix is a matrix obtained by deleting a to-be-deleted row in a generation matrix based on a target information bit index table, and the generation matrix is an N×N matrix obtained through calculation based on G_{N}=F^{⊗n}, where G_{N} is the generation matrix, F^{⊗n} is F raised to a Kronecker power, F^{⊗n}=F⊗F^{⊗(n-1)}, the target information bit index table is used to indicate locations of the K information bits and locations of N−K fixed bits, the generation matrix includes K reserved rows and N−K to-be-deleted rows, locations of the K reserved rows correspond to the locations of the K information bits, and locations of the N−K to-be-deleted rows correspond to the locations of the N−K fixed bits.

A beneficial effect of the second manner is as follows: Because the target coding table stores the simplified matrix, when calculating the target coding sequence, the sending apparatus can obtain the simplified matrix by simply querying the target coding table, and calculate the target coding sequence by using the simplified matrix, and does not need to calculate the generation matrix in real time, thereby reducing complexity of polar channel coding.

In one embodiment, the target coding table is used to store a one-to-one mapping relationship between 2^{K} pieces of candidate to-be-coded data and 2^{K} candidate coding sequences. The following describes the three different implementations separately.

In one embodiment, the 2^{K} candidate coding sequences are 2^{K} coding sequences obtained by respectively coding the 2^{K} pieces of candidate to-be-coded data based on the target coding scheme by using the polar channel coding method.

A beneficial effect of the first manner is as follows: The target coding sequence obtained by coding the K information bits can be obtained by querying the target coding table. After the target coding sequence is obtained, puncturing or repetition processing may be performed on the target coding sequence according to a requirement, so as to perform rate matching.

In another embodiment, the 2^{K} candidate coding sequences are 2^{K} coding sequences obtained by respectively coding the 2^{K} pieces of candidate to-be-coded data based on the target coding scheme by using the polar channel coding method, and further performing puncturing processing on the coded data.

A beneficial effect of the second manner is as follows: The target coding sequence obtained by coding the K information bits and further performing puncturing processing on the coded information bits can be obtained by querying the target coding table. In other words, in this manner, polar coding and rate matching can be both implemented by querying the target coding table, so that operating efficiency of the sending apparatus can be effectively improved.

In yet another embodiment, the 2^{K} candidate coding sequences are 2^{K} coding sequences obtained by respectively coding the 2^{K} pieces of candidate to-be-coded data based on the target coding scheme by using the polar channel coding method, and further performing repetition processing on the coded data.

A beneficial effect of the third manner is as follows: The target coding sequence obtained by coding the K information bits and further performing repetition processing on the coded information bits can be obtained by querying the target coding table. In other words, in this manner, polar coding and rate matching can be both implemented by querying the target coding table, so that operating efficiency of the sending apparatus can be effectively improved.

An embodiment in which the sending apparatus codes the K information bits based on the target coding table to obtain the target coding sequence varies with content of the target coding table. Details are provided below.

When the target coding table is used to store the generation matrix, the sending apparatus extends the K information bits to N to-be-coded bits based on a target information bit index table, where the N to-be-coded bits include the K information bits and N−K fixed bits, and the target information bit index table is used to indicate locations of the K information bits and locations of the N−K fixed bits. The sending apparatus multiplies the N to-be-coded bits by the N×N generation matrix to obtain the target coding sequence.

When the target coding table is used to store the generation matrix, the sending apparatus simplifies the N×N target matrix into a K×N simplified matrix based on a target information bit index table, where the target information bit index table is used to indicate locations of the K information bits and locations of N−K fixed bits, the generation matrix includes K reserved rows and N−K to-be-deleted rows, locations of the K reserved rows correspond to the locations of the K information bits, and locations of the N−K to-be-deleted rows correspond to the locations of the N−K fixed bits. The sending apparatus multiplies the K information bits by the K×N simplified matrix to obtain the target coding sequence.

When the target coding table is used to store the simplified matrix, the sending apparatus multiplies the K information bits by a K×N simplified matrix to obtain the target coding sequence.

When the target coding table is used to store the one-to-one mapping relationship between the 2^{K} pieces of candidate to-be-coded data and the 2^{K} candidate coding sequences, the sending apparatus queries the target coding table based on the K information bits, to select the target coding sequence from the candidate coding sequences, where the K information bits belong to the candidate to-be-coded data.

In some embodiments, after determining the target coding scheme, the sending apparatus further needs to send the target coding scheme to a receiving apparatus, so that the receiving apparatus performs decoding based on the target coding scheme. The sending apparatus may send the target coding scheme in the following two manners:

In one embodiment, if a quantity of the candidate coding schemes is greater than a preset threshold, the sending apparatus sends the target coding scheme to the receiving apparatus, so that the receiving apparatus performs decoding based on the target coding scheme, where the target coding scheme belongs to the candidate coding schemes.

A beneficial effect of the first manner is as follows: If there are a relatively large quantity of candidate coding schemes, sending the target coding scheme in the first manner can effectively reduce transmission overheads required for transmitting the target coding scheme.

In another embodiment, if a quantity of the candidate coding schemes is less than or equal to a preset threshold, the sending apparatus sends a target index to the receiving apparatus, so that the receiving apparatus determines the target coding scheme based on the target index, and performs decoding based on the target coding scheme, where the target index belongs to candidate indexes, and there is a one-to-one correspondence between the candidate indexes and the candidate coding schemes.

A beneficial effect of the second manner is as follows: If there are a relatively small quantity of candidate coding schemes, sending the target coding scheme in the second manner can effectively reduce transmission overheads required for transmitting the target coding scheme.

According to a second aspect, a polar channel decoding method is provided, including:

receiving, by a receiving apparatus, a target coding scheme, where the target coding scheme is used to indicate a mother code length N and a quantity K of information bits that are used during coding, N is an integral power of 2, both N and K are positive integers, and N>K;

determining, by the receiving apparatus, locations of the information bits in the target coding scheme based on a target information bit index table, where the target information bit index table is used to store the locations of the K information bits and locations of N−K fixed bits;

determining, by the receiving apparatus, 2^{K} possible decoding results in an exhaustive manner based on the target coding scheme and the locations of the information bits, where each of the 2^{K} possible decoding results includes N bits; and

selecting, by the receiving apparatus, an optimal possible decoding result from the 2^{K} possible decoding results as a decoding result of polar coding.

In some embodiments, the obtaining, by a receiving apparatus, a target coding scheme is specifically:

when a quantity of candidate coding schemes is greater than a preset threshold, determining, by the receiving apparatus, the target coding scheme by receiving the target coding scheme, where the target coding scheme belongs to the candidate coding schemes; or

when a quantity of candidate coding schemes is less than or equal to a preset threshold, selecting, by the receiving apparatus, the target coding scheme from the candidate coding schemes by receiving a target index, where the target index belongs to candidate indexes, and there is a one-to-one correspondence between the candidate indexes and the candidate coding schemes.

In some embodiments, the selecting, by the receiving apparatus, an optimal possible decoding result from the 2^{K} possible decoding results as a decoding result of the polar coding is specifically:

selecting, by the receiving apparatus based on a maximum likelihood method, an optimal possible decoding result from the 2^{K} possible decoding results as the decoding result of the polar coding.

According to a third aspect, a sending apparatus is provided, including a unit configured to perform the method according to the first aspect.

According to a fourth aspect, a receiving apparatus is provided, including a unit configured to perform the method according to the second aspect.

According to a fifth aspect, a sending apparatus is provided, including a memory and a processor and a communications module that are coupled to the memory. The communications module is configured to send or receive data sent from the outside; the memory is configured to store program code of the method according to the first aspect; and the processor is configured to execute the program code stored in the memory, that is, to perform the method according to the first aspect.

According to a sixth aspect, a receiving apparatus is provided, including a memory and a processor and a communications module that are coupled to the memory. The communications module is configured to send or receive data sent from the outside, the memory is configured to store program code of the method according to the second aspect; and the processor is configured to execute the program code stored in the memory, that is, to perform the method according to the second aspect.

According to a seventh aspect, a computer readable storage medium is provided. The computer readable storage medium stores an instruction; and when the instruction runs on a computer, the computer performs the method according to the first aspect and/or the second aspect.

According to an eighth aspect, a computer program product that includes an instruction is provided. When the instruction runs on a computer, the computer performs the method according to the first aspect and/or the second aspect.

According to a ninth aspect, a digital wireless communications system is provided, including a sending apparatus and a receiving apparatus. The sending apparatus is capable of communicating with the receiving apparatus, the sending apparatus may be the sending apparatus described in the foregoing third aspect, and the receiving apparatus may be the receiving apparatus described in content of the foregoing fourth aspect. The sending apparatus may alternatively be the sending apparatus described in content of the foregoing fifth aspect, and the receiving apparatus may alternatively be the receiving apparatus described in content of the foregoing sixth aspect.

### BRIEF DESCRIPTION OF DRAWINGS

To describe the technical solutions in the embodiments of the present application more clearly, the following briefly describes the accompanying drawings required for describing the embodiments of the present application.

FIG. 1 is a schematic structural diagram of a digital wireless communications system according to an embodiment of this application;

FIG. 2 is a flowchart of a polar channel coding method applied to a sending apparatus side in the prior art;

FIG. 3 is a flowchart of a polar channel coding method according to an embodiment of this application;

FIG. 4A to FIG. 4C are flowcharts of specific implementations of the polar channel coding method shown in FIG. 3;

FIG. 5 is a flowchart of a polar decoding method according to an embodiment of this application;

FIG. 6 is a schematic diagram of function modules of a digital wireless communications system and related devices according to an embodiment of the present application; and

FIG. 7 is a schematic structural diagram of an apparatus according to an embodiment of the present application.

### DESCRIPTION OF EMBODIMENTS

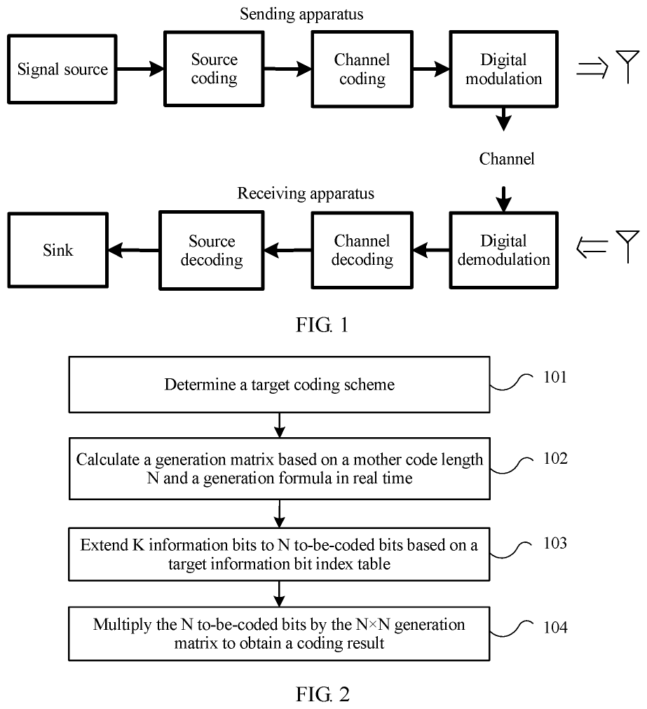

The following first describes a digital wireless communications system in an embodiment of this application. As shown in FIG. 1, the digital wireless communications system usually includes a sending apparatus and a receiving apparatus. A wireless communication connection may exist between the sending apparatus and the receiving apparatus, to implement data communication between the sending apparatus and the receiving apparatus. The following describes in detail a process of data communication between the sending apparatus and the receiving apparatus.

In the sending apparatus, an electrical signal output by a signal source is converted into a radio signal sequentially after source coding, channel coding, and digital modulation processing, and the radio signal is sent. The source coding may be used to convert a continuous analog electrical signal into a discrete digital signal, and compress data. The channel coding is used to add redundancy information to the digital signal to obtain a coded signal, and the redundancy information is related to the digital signal. The digital modulation is used to migrate a spectrum of the coded signal to a high frequency, to form a radio signal suitable for being transmitted on a channel.

In the receiving apparatus, the received radio signal is converted into an electrical signal sequentially after digital demodulation, channel decoding, and source decoding processing, and the electrical signal is output to a sink. The digital demodulation is used to migrate a spectrum of a radio signal suitable for being transmitted on a channel from a high frequency to a low frequency, to form a coded signal. The channel decoding is used to detect and correct an error generated in a digital signal transmission process based on a correlation between redundancy information and a digital signal, to improve a capability of the digital signal to resist different types of interference during transmission on a channel. The source decoding is used to decompress data, and convert a discrete digital signal into a continuous analog electrical signal. It may be learned from the foregoing descriptions that the data demodulation, the channel decoding, and the source decoding are respectively inverse processes of the digital modulation, the channel coding, and the source coding.

It should be understood that the digital wireless communications system may be a second generation digital mobile communications system, such as a Global System for Mobile Communications (GSM) or a general packet radio service (“GPRS” for short) system. Alternatively, the digital wireless communications system may be a third generation digital mobile communications system, such as a Code Division Multiple Access (CDMA) system, a Wideband Code Division Multiple Access (WCDMA) system, or a Universal Mobile Telecommunications System (UMTS). Alternatively, the digital wireless communications system may be a fourth generation digital mobile communications system, such as a Long Term Evolution (LTE) system, an LTE frequency division duplex (FDD) system, or an LTE time division duplex (TDD) system. Alternatively, the digital wireless communications system may be a fifth generation digital mobile communications system or a subsequent evolved digital mobile communications system. This is not specifically limited in this application.

It should be noted that when the sending apparatus is a base station in the digital wireless communications system, the receiving apparatus may be a terminal device in the digital wireless communications system. On the contrary, when the sending apparatus is a terminal device in the digital wireless communications system, the receiving apparatus may be a base station in the digital wireless communications system. It should be understood that the sending apparatus and the receiving apparatus may alternatively be other devices in the digital wireless communications system. This is not specifically limited herein.

It should be understood that a linear block code may be used for the channel coding and channel decoding in the digital wireless communications system, for example, Turbo Code 2.0, LDPC coding, or polar coding. In the embodiments of this application, polar coding is used for the channel coding and the channel decoding. In other words, on a sending apparatus side, after source coding processing is performed on the electrical signal output by the signal source, channel coding processing is performed in a polar coding manner, and finally, digital modulation processing is further performed to obtain the radio signal. On a receiving apparatus side, after digital demodulation processing is performed on the received radio signal, channel decoding processing is performed in a polar coding manner, and finally, source decoding is further performed to obtain the electrical signal and input the electrical signal to the sink.

FIG. 2 is a flowchart of a polar channel coding method applied to a sending apparatus side in the prior art. As shown in FIG. 2, the method includes the following steps:

101: A sending apparatus obtains a target coding scheme, where the target coding scheme is used to indicate a quantity K of information bits and a mother code length N that are used during coding. The K information bits may include but are not limited to any one or more of the following types of check bits: CRC (cyclic redundancy check) bits, PC (parity check) bits, hash bits, and other check bits.

102: The sending apparatus calculates a generation matrix in real time, based on the mother code length N and a generation formula G_{N}=F^{⊗n}, where F^{⊗n} is F raised to a Kronecker power, F^{⊗n}=F⊗F^{⊗(n-1)}, and

$$F = [ \begin{matrix}1 & 0 \\ 1 & 1\end{matrix} ] .$$

103: The sending apparatus extends the K information bits to N to-be-coded bits u_{N} based on a target information bit index table, where the N to-be-coded bits u_{N} include the K information bits and N−K fixed bits, and the target information bit index table is used to indicate locations of the K information bits and locations of the N−K fixed bits.

104: The sending apparatus multiplies the N to-be-coded bits u_{N} by the N×N generation matrix G_{N} to obtain a coding sequence x_{N}=u_{N}G_{N}.

It may be understood that step 102 of calculating the generation matrix G_{N} in real time is a relatively complex process, and specifically needs to include the following N steps:

Step 1: Determine a quantity N of to-be-coded bits.

Step 2: Calculate F^{⊗2}=F⊗F where

$$F = [ \begin{matrix}1 & 0 \\ 1 & 1\end{matrix} ] .$$

Step 3: Calculate F^{⊗3}=F⊗F^{⊗2}.

Step 4: Calculate F^{⊗4}=F⊗F^{⊗3}.

. . .

Step N: Calculate G_{N}=F^{⊗N}=F⊗F^{⊗N-1}.

It may be learned from the foregoing process that the calculation of the generation matrix by the sending apparatus requires N−1 iterations. Consequently, a lot of computing time and computing resources need to be consumed. Especially, as the mother code length N increases, a process in which the sending apparatus calculates the generation matrix becomes more complex, and cannot meet a requirement of an application scenario that requires a low latency and a simple hardware system.

To resolve the foregoing problem, the embodiments of this application provide a polar channel coding method, a device, and a system, so that there is no need to calculate a generation matrix G_{N} in real time, thereby reducing channel coding complexity, and avoiding consumption of a lot of computing time and computing resources. Descriptions are provided below separately.

A main principle related to the embodiments of the present application includes: A sending apparatus may select a target coding scheme from a plurality of candidate coding schemes, select a target coding table corresponding to the target coding scheme from a plurality of candidate coding tables based on the target coding scheme, and perform channel coding based on the target coding table. The plurality of candidate coding schemes and the plurality of candidate coding tables may be preset on a sending apparatus side.

In the embodiments of this application, the target coding scheme is used to indicate a quantity K of information bits and a mother code length N that are used during the channel coding. The mother code length N and the quantity K of the information bits both affect a code rate, and the following relationships exist between the mother code length N, the quantity K of information bits, and the code rate.

Specifically, when a same mother code length N is used, a larger quantity K of information bits indicates a higher code rate. For example, when the mother code length is 256 and the quantity of information bits is 128 in the target coding scheme, the code rate of the target coding scheme is ½; or when the mother code length is 256 and the quantity of information bits is 64 in the target coding scheme, the code rate of the target coding scheme is ¼. The example is merely used to describe the embodiments of the present application, and should not be construed as a specific limitation.

Specifically, when a same quantity K of information bits is used, a longer mother code length N indicates a lower code rate. For example, when the mother code length is 256 and the quantity of information bits is 128 in the target coding scheme, the code rate of the target coding scheme is ½; or when the mother code length is 512 and the quantity of information bits is 128 in the target coding scheme, the code rate of the target coding scheme is ¼. The example is merely used to describe the embodiments of the present application, and should not be construed as a specific limitation.

It may be understood that when a same mother code length N is used, a higher code rate indicates a higher data transmission rate, but correspondingly results in a lower anti-interference capability; and when a same mother code length N is used, a lower code rate indicates a lower data transmission rate, but correspondingly results in a higher anti-interference capability.

In an actual application, the sending apparatus may select the target coding scheme from the plurality of candidate coding schemes based on a transmission rate requirement and channel quality. For example, if a relatively high transmission rate is required, when a same mother code length N is used, the sending apparatus may select a candidate coding scheme with a relatively high code rate as the target coding scheme, to improve a data transmission rate; or if a relatively low transmission rate is required, when a same mother code length N is used, the sending apparatus may select a candidate coding scheme with a relatively low code rate as the target coding scheme, to improve an anti-interference capability of data. For another example, if the channel quality is good, when a same mother code length N is used, the sending apparatus may select a candidate coding scheme with a relatively high code rate as the target coding scheme, to improve a data transmission rate; or if the channel quality is relatively poor, when a same mother code length N is used, the sending apparatus may select a candidate coding scheme with a lower code rate as the target coding scheme, to improve an anti-interference capability of data. It may be understood that the examples of selecting a target coding scheme are merely intended to describe the embodiments of this application. In an actual application, the target coding scheme may alternatively be selected based on both the transmission rate requirement and the channel quality, or the target coding scheme may be selected based on another factor. This is not specifically limited herein.

In the embodiments of this application, an influencing factor of the transmission rate requirement includes at least one of the following: a service type (e.g., a video, voice, or a text), a charging type (with a charge or free of charge), or a user type (a VIP user or a common user). Usually, a transmission rate requirement of video type data is higher than a transmission rate requirement of voice type data, and a transmission rate requirement of a voice type service is higher than a transmission rate requirement of a text type service. A transmission rate requirement of data of a charged service is higher than a transmission rate requirement of data of a free-of-charge service. A transmission rate requirement of data of a VIP user is higher than a transmission rate requirement of data of a common user. The transmission rate requirement may further include another influencing factor, such as a quality of service class. This is not specifically limited in this application.

In the embodiments of this application, an influencing factor of the channel quality includes at least one of the following: a fading characteristic (for example, whether an obstacle exists, a path length, or whether a Doppler frequency shift exists), ambient noise (such as white noise or Gaussian noise), or interference (such as adjacent channel interference or co-channel interference). Usually, channel quality of a channel without an obstacle is superior to channel quality of a channel with an obstacle; channel quality of a channel with a relatively long path is superior to channel quality of a channel with a relatively short path; and channel quality of a channel without a Doppler frequency shift is superior to channel quality of a channel with a Doppler frequency shift. In an actual application, the channel quality may further include another influencing factor, such as weather or heat radiation. This is not specifically limited in this application.

It should be noted that in addition to indicating the mother code length N and the quantity K of information bits, the target coding scheme may be used to indicate more factors that affect the channel coding, such as a quantity of punctured bits and a quantity of repeated bits. It may be understood that the target coding scheme may be further used to indicate a CRC check bit or another check bit, such as a parity check bit. This is not specifically limited herein.

In the embodiments of this application, the sending apparatus needs to notify a receiving apparatus of the selected target coding scheme, so that the receiving apparatus performs channel decoding based on the target coding scheme. Specifically, the sending apparatus may notify the receiving apparatus of the selected target coding scheme in the following two embodiments:

In one embodiment, the sending apparatus sends the target coding scheme to the receiving apparatus. For example, if the mother code length is 16 and the quantity of information bits is 8 in the selected target coding scheme, the sending apparatus may send the mother code length 16 and the quantity 8 of information bits to the receiving apparatus. After receiving the mother code length 16 and the quantity 8 of information bits, the receiving apparatus may learn that the mother code length is 16 and the quantity of information bits is 8 in the target coding scheme selected by the sending apparatus. It may be understood that the example is merely used to describe the embodiments of this application, and should not be construed as a specific limitation.

In another embodiment, the sending apparatus sends a target index rather than the target coding scheme to the receiving apparatus. Specifically, the sending apparatus side and a receiving apparatus side store a same index table, and the index table is used to store a correspondence between a candidate index and a candidate coding scheme. On the sending apparatus side, the sending apparatus may query the index table based on the selected target coding scheme, to find the target index corresponding to the target coding scheme from a plurality of candidate indexes in the index table, and send the target index to the receiving apparatus. On the receiving apparatus side, the receiving apparatus queries the index table based on the received target index, to find the target coding scheme corresponding to the target index from the plurality of candidate coding schemes in the index table.

For example, both the sending apparatus side and the receiving apparatus side store an index table shown in Table 1. For ease of description, a simple manner is used below to represent a candidate coding scheme. For example, a candidate coding scheme in which a mother code length is 32 and a quantity of information bits is 16 is denoted as (32, 16).

TABLE 1
Index table

| Candidate coding scheme | Candidate index |
|---|---|
| (32, 16) | 00 |
| (32, 8) | 01 |
| (16, 8) | 10 |
| (16, 4) | 11 |

On the sending apparatus side, when the sending apparatus needs to send a selected target coding scheme (16, 8) to the receiving apparatus, the sending apparatus may query the index table (as shown in Table 1) on the sending apparatus side, to obtain a target index 10 corresponding to the target coding scheme (16, 8). Then the sending apparatus sends the target index 10 to the receiving apparatus in an explicit or implicit manner (for example, sends a channel type corresponding to the target index or a service type corresponding to the target index). After receiving the target index 10, the receiving apparatus queries the index table (as shown in Table 1) on the receiving apparatus side based on the target index 10, to obtain the target coding scheme (16, 8) corresponding to the target index 10. It may be understood that the example is merely used to describe the embodiments of this application, and should not be construed as a specific limitation.

Transmission overheads used by the sending apparatus to send the target coding scheme (16, 8) to the receiving apparatus in the first manner and the second manner when a quantity of candidate coding schemes varies are calculated below.

It is assumed that there are only four candidate coding schemes. If the first manner is used, transmission of the target coding scheme (16, 8) by the sending apparatus to the receiving apparatus requires overheads of seven bits (transmission of the mother code length 16 requires four bits, and transmission of the quantity 8 of information bits requires three bits). However, if the second manner is used, transmission of a target index corresponding to the target coding scheme (16, 8) by the sending apparatus to the receiving apparatus requires two bits. Therefore, overheads required in the second manner are smaller than the overheads required in the first manner.

It is assumed that there are 1024 candidate coding schemes. If the first manner is used, transmission of the target coding scheme (16, 8) by the sending apparatus to the receiving apparatus requires overheads of seven bits (transmission of the mother code length 16 requires four bits, and transmission of the quantity 8 of information bits requires three bits). However, if the second manner is used, transmission of a target index corresponding to the target coding scheme (16, 8) by the sending apparatus to the receiving apparatus requires 10 bits. Therefore, the overheads required in the first manner are smaller than overheads required in the second manner.

In conclusion, when there are a relatively small quantity of candidate coding schemes, the sending apparatus may send the target coding scheme to the receiving apparatus in the second manner; or when there are a relatively large quantity of candidate coding schemes, the sending apparatus may send the target coding scheme to the receiving apparatus in the first manner. In a specific implementation, it may be considered that when the quantity of candidate coding schemes is less than a preset threshold, there are a relatively small quantity of candidate coding schemes; or

when the quantity of candidate coding schemes is greater than or equal to a preset threshold, there are a relatively large quantity of candidate coding schemes. The preset threshold is obtained through statistical analysis based on a large amount of practical experience.

In the embodiments of this application, after the two manners used by the sending apparatus to notify the receiving apparatus of the selected target coding scheme are described, the following several possible implementation modes of the target coding table are described in detail below separately:

In a first mode, the target coding table is used to store a mapping relationship that is between candidate to-be-coded data and a candidate coding sequence and that corresponds to the target coding scheme. The target coding table in the embodiments of this application may be shown in Table 2:

TABLE 2
Target coding table

| Candidate to-be-coded data | Candidate coding sequence |
|---|---|
| A₁ | B₁ |
| A₂ | B₂ |
| A₃ | B₃ |
| . . . | . . . |
| A₂^{k} | B₂^{k} |

K is the quantity of information bits; candidate to-be-coded data A₁, A₂, A₃, . . . , and A₁^{k} are possible values of the K information bits enumerated by using an exhaustive method; and candidate coding sequences B₁, B₂, B₃, . . . , and B₂^{k} may be coding sequences obtained by respectively coding the candidate to-be-coded data A₁, A₂, A₃, . . . , and A₂^{k} based on the target coding scheme by using an existing polar channel coding method. It should be understood that the candidate coding sequences B₁, B₂, B₃, . . . , and B₂^{k} may alternatively be coding sequences obtained by respectively coding the candidate to-be-coded data A₁, A₂, A₃, . . . , and A₂^{k} based on the target coding scheme by using an existing polar channel coding method, and further performing processing on the coded data. The processing may be puncturing processing or repetition processing, and the processing may further include check processing (such as a CRC check or a parity check) and the like.

In example 1, the candidate coding sequence B₁, B₂, B₃, . . . , and B₂^{k} are coding sequences obtained by respectively coding the candidate to-be-coded data A₁, A₂, A₃, . . . , and A₁^{k} based on the target coding scheme by using the existing polar channel coding method. For example, assuming that the mother code length is 8 and the quantity of information bits is 2, the target coding table is shown in Table 3:

TABLE 3
Target coding table of specific example 1

| Candidate to-be-coded data | Candidate coding sequence |
|---|---|
| 00 | 00000000 |
| 01 | 11111111 |
| 10 | 10101010 |
| 11 | 01010101 |

Candidate to-be-coded data 00, 01, 10, and 11 are possible values of the two information bits enumerated by using the exhaustive method, and candidate coding sequences 00100000, 11011111, 110111110, and 001000001 are coding sequences obtained by respectively coding the candidate to-be-coded data 00, 01, 10, and 11 based on the target coding scheme by using the existing polar channel coding method. It should be understood that Table 3 is merely an example and should not be construed as a specific limitation.

In example 2, the candidate coding sequence B₁, B₂, B₃, . . . , and B₂^{k} are coding sequences obtained by respectively coding the candidate to-be-coded data A₁, A₂, A₃, . . . , and A₂^{k} based on the target coding scheme by using the existing polar channel coding method, and further performing puncturing processing on the coded data. For example, assuming that the mother code length is 8 and the quantity of information bits is 2, the target coding table is shown in Table 4:

TABLE 4
Target coding table of specific example 2

| | First candidate | Second candidate |
|---|---|---|
| Candidate | coding sequence | coding sequence |
| to-be-coded | (Coding rate of 2/7, | (Coding rate of 1/3, |
| data | bit 2) | and bits 2 and 6) |
| 00 | 0000000 | 000000 |
| 01 | 1111111 | 111111 |
| 10 | 1001010 | 100100 |
| 11 | 0110101 | 011011 |

Note: In Table 4, (coding rate 2/7, bit 2) indicates that a coding rate is 2/7 and a location of a punctured bit is bit 2; and (Coding rate of 1/3, and bits 2 and 6) indicates that a coding rate is 1/3 and locations of punctured bits are bit 2 and bit 6.

Candidate to-be-coded data 00, 01, 10, and 11 are possible values of the two information bits enumerated by using the exhaustive method; first candidate coding sequences 0000000, 1111111, 1001010, and 0110101 are coding sequences obtained by respectively coding the candidate to-be-coded data 00, 01, 10, and 11 based on the target coding scheme by using the existing polar channel coding method (for a coding result, refer to Table 3), and further performing puncturing processing on bit 2; and second candidate coding sequences 000000, 111111, 100100, and 011011 are coding sequences obtained by respectively coding the candidate to-be-coded data 00, 01, 10, and 11 based on the target coding scheme by using the existing polar channel coding method (for a coding result, refer to Table 3), and further performing puncturing processing on bit 2 and bit 6. It should be understood that Table 4 is merely an example. In an actual application, there may alternatively be one, three, four, or more candidate coding sequences corresponding to the candidate to-be-coded data, and a quantity of punctured bits and locations of the punctured bits may be set based on an actual requirement.

In example 3, the candidate coding sequence B₁, B₂, B₃, . . . , and B₂^{k} are coding sequences obtained by respectively coding the candidate to-be-coded data A₁, A₂, A₃, . . . , and A₂^{k} based on the target coding scheme by using the existing polar channel coding method, and further performing repetition processing on the coded data. For example, assuming that the mother code length is 8 and the quantity of information bits is 2, the target coding table is shown in Table 5:

TABLE 5
Target coding table of specific example 3

| | First candidate | Second candidate |
|---|---|---|
| Candidate | coding sequence | coding sequence |
| to-be-coded | (Coding rate of 2/9, | (Coding rate of 1/5, |
| data | bit 2) | and bits 2 and 6) |
| 00 | 000000000 | 0000000000 |
| 01 | 111111111 | 1111111111 |
| 10 | 101101010 | 1011010110 |
| 11 | 010010101 | 0100101001 |

Note: In Table 5, “(Coding rate 2/9, bit 2)” indicates that a coding rate is 2/9 and a location of a repeated bit is bit 2; and “(Coding rate of 1/5, and bits 2 and 6)” indicates that a coding rate is 1/5 and locations of repeated bits are bit 2 and bit 6.

Candidate to-be-coded data 00, 01, 10, and 11 are possible values of the two information bits enumerated by using the exhaustive method; first candidate coding sequences 000000000, 111111111, 101101010, and 010010101 are coding sequences obtained by respectively coding the candidate to-be-coded data 00, 01, 10, and 11 based on the target coding scheme by using the existing polar channel coding method (for a coding result, refer to Table 3), and further performing repetition processing on bit 2; and second candidate coding sequences 0000000000, 1111111111, 1011010110, and 0100101001 are coding sequences obtained by respectively coding the candidate to-be-coded data 00, 01, 10, and 11 based on the target coding scheme by using the existing polar channel coding method (for a coding result, refer to Table 3), and further performing repetition processing on bit 2 and bit 6. It should be understood that Table 5 is merely an example. In an actual application, there may alternatively be one, three, four, or more candidate coding sequences corresponding to the candidate to-be-coded data, or a bit at a location may be repeated at other locations for a plurality of times, or other manners may be used. Specifically, a quantity of repeated bits in a candidate coding sequence and locations of the repeated bits may be set based on an actual requirement.

In a second mode, the target coding table is used to store a generation matrix corresponding to the target coding scheme. The generation matrix is an N×N matrix obtained through calculation based on G_{N}=F^{⊗n}, where G_{N} is the generation matrix, F^{⊗n} is F raised to a Kronecker power, and F^{⊗n}=F⊗F^{⊗(n-1)}.

For example, a target coding scheme in which a mother code length is 8 and a quantity of information bits is 2 is used as an example, and a generation matrix may be obtained through calculation based on a formula G₈F^{⊗8}:

$${G}_{8} = [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] .$$

In this case, content stored in the target coding table is the generation matrix G₈. It should be understood that the foregoing example is merely for an illustration purpose. In an actual application, the mother code length of the generation matrix may alternatively be another integral power of 2, for example, 2, 4, 16, or 32.

In a third mode, the target coding table is used to store a simplified matrix corresponding to the target coding scheme. The simplified matrix is a matrix obtained by simplifying a generation matrix based on a target information bit index table.

In this embodiment, the target information bit index table records a channel capacity or reliability of each of N bits (the mother code length of the target coding scheme is N). K bits may be selected from the N bits as information bits based on the channel capacity that is of each of the N bits and that is recorded in the target information bit index table, and N−K bits are used as fixed bits. In other words, the target information bit index table may be used to indicate locations of the K information bits and locations of the N−K fixed bits.

In one embodiment, K bits that have largest channel capacities in the N bits may be used as information bits based on the channel capacity of each of the N bits, and the remaining N−K bits are used as fixed bits. For example, assuming that N=8, channel capacities of all eight bits are recorded in the target information bit index table as follows:

[0.0039, 0.1211, 0.1914, 0.6836, 0.3164, 0.8086, 0.8789, and 0.9961].

Two bits [6 and 7] that have largest channel capacities in the eight bits may be used as information bits, and the remaining six bits [0, 1, 2, 3, 4, and 5] are used as fixed bits.

In one embodiment, bits whose row weights are greater than a weight threshold T may be selected from the N bits; and then K bits that have largest channel capacities are selected, from the bits whose row weights are greater than the weight threshold T, as information bits based on the channel capacity of each of the N bits, and the remaining N−K bits are used as fixed bits. For example, assuming that N=8, channel capacities of all eight bits are recorded in the target information bit index table as follows:

[0.0039, 0.1211, 0.1914, 0.6836, 0.3164, 0.8086, 0.8789, and 0.9961].

Row weights of all the eight bits are recorded in a candidate weight table as follows:

[1, 2, 2, 4, 2, 4, 4, and 8].

Assuming that the row weight threshold is 3, bits [3, 5, 6, and 7] whose row weights are greater than the weight threshold 3 are selected from the eight bits; and then two bits [6, 7] that have largest channel capacities are selected, from the bits whose row weights are greater than the weight threshold 3, as information bits, and the remaining 6 bits [0, 1, 2, 3, 4, and 5] as used as fixed bits.

In this embodiment, the generation matrix is an N×N matrix obtained through calculation based on G_{N}=F^{⊗n}, where G_{N} is the generation matrix, F^{⊗n} is F raised to a Kronecker power, and F^{⊗n}=F⊗F^{⊗(n-1)}. For example, a target coding scheme in which a mother code length is 8 and a quantity of information bits is 2 is used as an example, and a generation matrix may be obtained through calculation based on a formula G₈=F^{⊗8}:

$${G}_{8} = [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] .$$

In this embodiment, the simplified matrix is obtained by deleting a to-be-deleted row from the generation matrix and reserving only a reserved row in the generation matrix. The generation matrix includes K reserved rows and N−K to-be-deleted rows. Locations of the K reserved rows correspond to the locations that are of the K information bits and that are indicated by the target information bit index table, and locations of the N−K to-be-deleted rows correspond to the locations that are of the N−K fixed bits and that are indicated by the target information bit index table.

For example, it is assumed that the mother code length is 8, the quantity of information bits is 2, the target information bit index table indicates bits [6 and 7] as information bits and bits [0, 1, 2, 3, 4, and 5] as fixed bits, and the generation matrix is

$${G}_{8} = [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] .$$

Rows [6 and 7] in the generation matrix correspond to the information bits [6 and 7], and rows [0, 1, 2, 3, 4, and 5] in the generation matrix correspond to the fixed bits [0, 1, 2, 3, 4, and 5]. Therefore, the rows [6 and 7] in the generation matrix are reserved rows, and the rows [0, 1, 2, 3, 4, and 5] in the generation matrix are to-be-deleted rows. A simplified matrix can be obtained by deleting the to-be-deleted rows [0, 1, 2, 3, 4, and 5] from the generation matrix and reserving only the reserved rows [6 and 7] in the generation matrix:

$${G}_{2 , 8} = [ \begin{matrix}1 & 0 & 1 & 0 & 1 & 0 & 1 & 0 \\ 1 & 1 & 1 & 0 & 1 & 1 & 1 & 1\end{matrix} ] .$$

In this case, content stored in the target coding table is the simplified matrix G_{2,8}. It should be understood that the foregoing example is merely for an illustration purpose and should not be construed as a specific limitation.

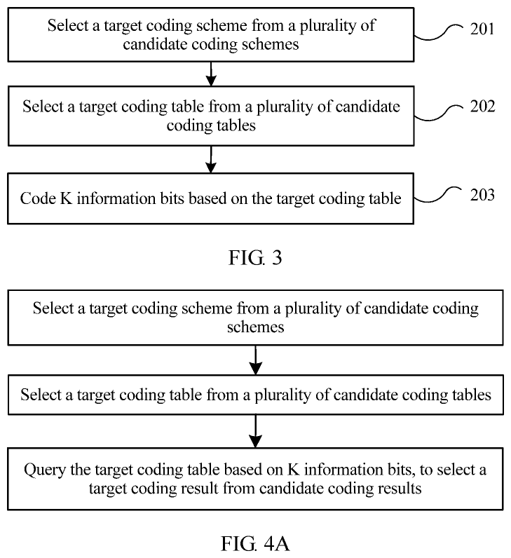

FIG. 3 is a flowchart of a polar channel coding method according to an embodiment of this application. As shown in FIG. 3, the polar channel coding method in this embodiment of this application includes the following steps.

201. A sending apparatus selects a target coding scheme from a plurality of candidate coding schemes, where the target coding scheme is used to indicate a quantity K of information bits and a mother code length N that are used during coding, N is an integral power of 2, both N and K are positive integers, and N>K.

202. The sending apparatus selects a target coding table from a plurality of candidate coding tables based on the target coding scheme, where the plurality of candidate coding tables are pre-stored in the sending apparatus.

It should be understood that for content about how to select the target coding scheme in step 201 and how to select the target coding table in step 202, refer to the foregoing descriptions. Details are not described herein again.

203. The sending apparatus codes the K information bits based on the target coding table to obtain a target coding sequence.

In this embodiment of this application, the sending apparatus may code the K information bits based on the target coding table, and does not need to calculate a generation matrix G_{N} in real time, thereby reducing channel coding complexity, and avoiding consumption of a lot of computing time and computing resources. The following describes in detail several main manners of coding the K information bits based on the target coding table.

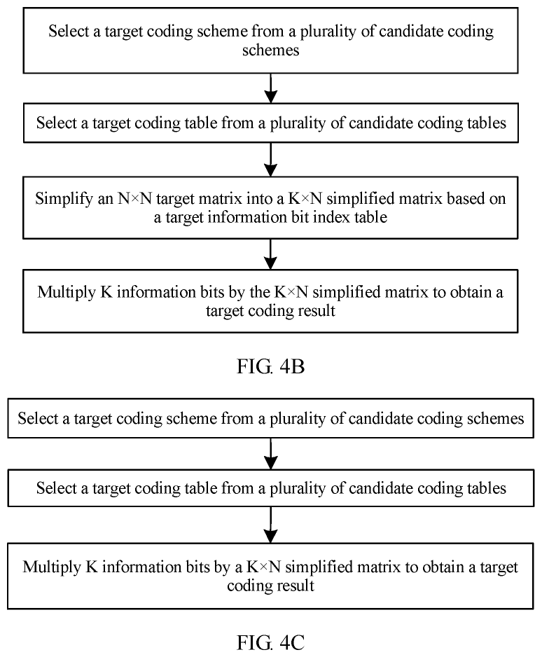

As shown in FIG. 4A, corresponding to the first mode of the target coding table, the sending apparatus may query the target coding table in the first manner based on the K information bits, to select the target coding sequence from candidate coding sequences.

In example 1, using Table 3 as an example for description, if an actual value of two information bits is 00, the sending apparatus may learn, by querying the target coding table shown in Table 3, that the target coding sequence is 00000000; or if an actual value of two information bits is 01, the sending apparatus may learn, by querying the target coding table shown in Table 3, that the target coding sequence is 11111111; or if an actual value of two information bits is 10, the sending apparatus may learn, by querying the target coding table shown in Table 3, that the target coding sequence is 10101010; or if an actual value of two information bits is 11, the sending apparatus may learn, by querying the target coding table shown in Table 3, that the target coding sequence is 01010101.

In example 2, using Table 4 as an example for description, if a coding rate is 2/7, a location of a punctured bit is bit 2, and an actual value of two information bits is 00, the sending apparatus may learn, by querying the target coding table shown in Table 4, that the target coding sequence is 0000000; or if a coding rate is 2/7, a location of a punctured bit is bit 2, and an actual value of two information bits is 01, the sending apparatus may learn, by querying the target coding table shown in Table 4, that the target coding sequence is 1111111; or if a coding rate is 2/7, a location of a punctured bit is bit 2, and an actual value of two information bits is 10, the sending apparatus may learn, by querying the target coding table shown in Table 4, that the target coding sequence is 1001010; or if a coding rate is 2/7, a location of a punctured bit is bit 2, and an actual value of two information bits is 11, the sending apparatus may learn, by querying the target coding table shown in Table 4, that the target coding sequence is 0110101.

If a coding rate is 1/3, locations of punctured bits are bit 2 and bit 6, and an actual value of two information bits is 00, the sending apparatus may learn, by querying the target coding table shown in Table 4, that the target coding sequence is 000000; or if a coding rate is 1/3, locations of punctured bits are bit 2 and bit 6, and an actual value of two information bits is 01, the sending apparatus may learn, by querying the target coding table shown in Table 4, that the target coding sequence is 111111; or if a coding rate is 1/3, locations of punctured bits are bit 2 and bit 6, and an actual value of two information bits is 10, the sending apparatus may learn, by querying the target coding table shown in Table 4, that the target coding sequence is 100100; or if a coding rate is 1/3, locations of punctured bits are bit 2 and bit 6, and an actual value of two information bits is 11, the sending apparatus may learn, by querying the target coding table shown in Table 4, that the target coding sequence is 011011.

In example 3, using Table 5 as an example for description, if a coding rate is 2/9, a location of a repeated bit is bit 2, and an actual value of two information bits is 00, the sending apparatus may learn, by querying the target coding table shown in Table 5, that the target coding sequence is 000000000; or if a coding rate is 2/9, a location of a repeated bit is bit 2, and an actual value of two information bits is 01, the sending apparatus may learn, by querying the target coding table shown in Table 5, that the target coding sequence is 111111111; or if a coding rate is 2/9, a location of a repeated bit is bit 2, and an actual value of two information bits is 10, the sending apparatus may learn, by querying the target coding table shown in Table 5, that the target coding sequence is 101101010; or if a coding rate is 2/9, a location of a repeated bit is bit 2, and an actual value of two information bits is 11, and the sending apparatus may learn, by querying the target coding table shown in Table 5, that the target coding sequence is 010010101.

If a coding rate is 1/5, locations of repeated bits are bit 2 and bit 6, and an actual value of two information bits is 00, the sending apparatus may learn, by querying the target coding table shown in Table 5, that the target coding sequence is 0000000000; or if a coding rate is 1/5, locations of repeated bits are bit 2 and bit 6, and an actual value of two information bits is 01, the sending apparatus may learn, by querying the target coding table shown in Table 5, that the target coding sequence is 1111111111; or if a coding rate is 1/5, locations of repeated bits are bit 2 and bit 6, and an actual value of two information bits is 10, the sending apparatus may learn, by querying the target coding table shown in Table 5, that the target coding sequence is 1011010110; or if a coding rate is 1/5, locations of repeated bits are bit 2 and bit 6, and an actual value of two information bits is 11, the sending apparatus may learn, by querying the target coding table shown in Table 5, that the target coding sequence is 0100101001.

As shown in FIG. 4B, corresponding to the second mode of the target coding table, the sending apparatus simplifies an N×N target matrix into a K×N simplified matrix based on a target information bit index table, and then the sending apparatus multiplies the K information bits by the K×N simplified matrix to obtain the target coding sequence.

It may be understood that for detailed content about simplifying the N×N target matrix to the K×N simplified matrix by the sending apparatus based on the target information bit index table, refer to content in the third possible implementation of the target coding table. Details are not described herein again.

An example is used to describe how the sending apparatus multiplies the K information bits by the K×N simplified matrix to obtain the target coding sequence. Assuming that two information bits are 10, and the K×N simplified matrix is

$${G}_{2 , 8} = [ \begin{matrix}1 & 0 & 1 & 0 & 1 & 0 & 1 & 0 \\ 1 & 1 & 1 & 0 & 1 & 1 & 1 & 1\end{matrix} ] ,$$

the target coding sequence is equal to

$$[ \begin{matrix}1 & 0\end{matrix} ] * [ \begin{matrix}1 & 0 & 1 & 0 & 1 & 0 & 1 & 0 \\ 1 & 1 & 1 & 0 & 1 & 1 & 1 & 1\end{matrix} ] .$$

The sending apparatus does not need to calculate a generation matrix based on the mother code length N and G_{N}.=F^{⊗n} in real time, thereby reducing channel coding complexity.

As shown in FIG. 4C, corresponding to the third mode of the target coding table, the sending apparatus multiplies the K information bits by a K×N simplified matrix to obtain the target coding sequence.

An example is used to describe how the sending apparatus multiplies the K information bits by the K×N simplified matrix to obtain the target coding sequence. Assuming that two information bits are 10, and the K×N simplified matrix is

$${G}_{2 , 8} = [ \begin{matrix}1 & 0 & 1 & 0 & 1 & 0 & 1 & 0 \\ 1 & 1 & 1 & 0 & 1 & 1 & 1 & 1\end{matrix} ] ,$$

the target coding sequence is equal to

$$[ \begin{matrix}1 & 0\end{matrix} ] * [ \begin{matrix}1 & 0 & 1 & 0 & 1 & 0 & 1 & 0 \\ 1 & 1 & 1 & 0 & 1 & 1 & 1 & 1\end{matrix} ] .$$

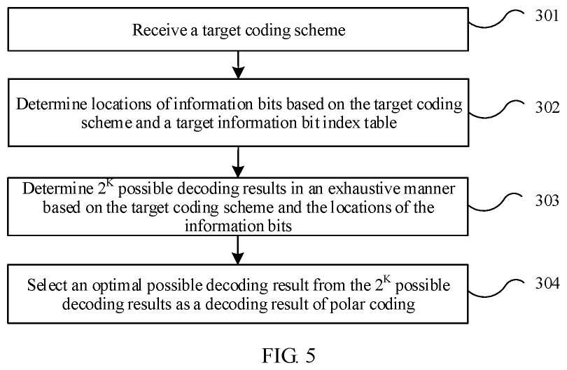

FIG. 5 is a flowchart of a polar decoding method according to an embodiment of this application. As shown in FIG. 5, the polar decoding method in this embodiment of this application includes the following steps.

301: A receiving apparatus receives a target coding scheme, where the target coding scheme is used to indicate a quantity K of information bits and a mother code length N that are used during coding, N is an integral power of 2, both N and K are positive integers, and N>K.

In this embodiment of this application, a manner in which the receiving apparatus obtains the target coding scheme is determined by a manner in which a sending apparatus sends the target coding scheme to the receiving apparatus. Therefore, for details, refer to content descriptions about how the sending apparatus notifies the receiving apparatus of the selected target coding scheme. Details are not described herein again.

302: The receiving apparatus determines locations of the information bits in the target coding scheme based on a target information bit index table, where the target information bit index table is used to store the locations of the K information bits and locations of N−K fixed bits.

For example, assuming that the mother code length is 8 and the quantity of information bits is 2 in the target coding scheme, and a sending apparatus side and a receiving apparatus side store a same target information bit index table, channel capacities of all eight bits are recorded in the target information bit index table as follows:

[0.0039, 0.1211, 0.1914, 0.6836, 0.3164, 0.8086, 0.8789, and 0.9961].

On the sending apparatus side, the sending apparatus uses, as information bits based on the target information bit index table stored on the sending apparatus side, two bits [6 and 7] that have largest channel capacities in the eight bits, and uses the remaining six bits [0, 1, 2, 3, 4, and 5] as fixed bits.

On the receiving apparatus side, the receiving apparatus determines, as locations of the information bits based on the target information bit index table stored on the receiving apparatus side, two bits [6 and 7] that have largest channel capacities in the eight bits, and determines the remaining six bits [0, 1, 2, 3, 4, and 5] as locations of the fixed bits.

303: The receiving apparatus determines 2^{K} possible decoding results in an exhaustive manner based on the target coding scheme and the locations of the information bits, where each of the 2^{K} possible decoding results includes N bits.

For example, it is assumed that the locations of the information bits are bits [6 and 7], and the locations of the fixed bits are bits [0, 1, 2, 3, 4, and 5]. Because a value of the fixed bit is usually set to 0, a possible decoding result definitely conforms to such a form:

[0, 0, 0, 0, 0, 0, *, *], where

* is a value of the information bit. All possible values of the two information bits are enumerated by using an exhaustive method, and four possible decoding results may be obtained:

[0, 0, 0, 0, 0, 0, 0, 0],

[0, 0, 0, 0, 0, 0, 0, 1],

[0, 0, 0, 0, 0, 0, 1, 0], and

[0, 0, 0, 0, 0, 0, 1, 1].

304: The receiving apparatus selects an optimal possible decoding result from the 2^{K} possible decoding results as a decoding result of the polar coding.

In this embodiment of this application, the receiving apparatus selects, based on a maximum likelihood method, an optimal possible decoding result from the 2^{K} possible decoding results as the decoding result of the polar coding. It should be understood that in addition to the maximum likelihood method, the receiving apparatus may select an optimal possible decoding result in another manner as the decoding result of the polar coding. This is not specifically limited in this application.

It should be noted that the polar coding method shown in FIG. 3 and the polar decoding method shown in FIG. 5 are independent of each other. In other words, when the sending apparatus performs coding by using the polar coding method in FIG. 3, the receiving apparatus may perform decoding by using a conventional decoding method, such as a successive cancellation (Successive cancellation, SC) algorithm, a belief propagation (Belief Propagation, BP) algorithm, an algorithm improved based on the SC algorithm, or an algorithm improved based on the BP algorithm, or may perform decoding by using the polar decoding method shown in FIG. 5. When the receiving apparatus performs decoding by using the polar decoding method shown in FIG. 5, the sending apparatus may use a conventional polar coding method, or may use the polar coding method shown in FIG. 3.

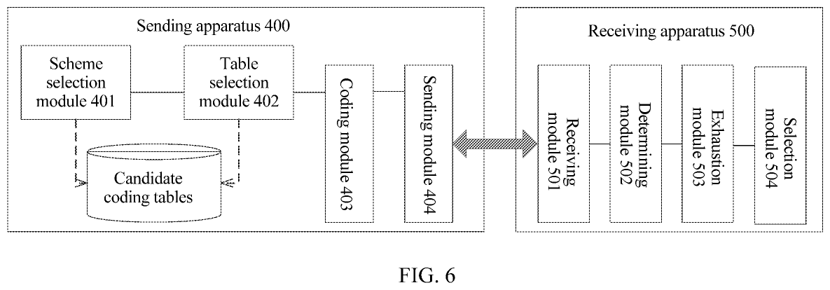

FIG. 6 shows an embodiment of a sending apparatus and a receiving apparatus according to an embodiment of the present application, and a schematic structural diagram of a communications system that includes the sending apparatus and the receiving apparatus. As shown in FIG. 6, a communication connection may exist between the sending apparatus 400 and the receiving apparatus 500, to implement data communication between the sending apparatus 400 and the receiving apparatus 500. The following provides detailed descriptions.

As shown in FIG. 6, the sending apparatus 400 may include a scheme selection module 401, a table selection module 402, and a coding module 403. A plurality of candidate coding tables are set on the sending apparatus side, so that the sending apparatus 400 may select an appropriate target coding table from the plurality of candidate coding tables.

The selection module 401 is configured to select a target coding scheme from a plurality of candidate coding schemes, where the target coding scheme is used to indicate a quantity K of information bits and a mother code length N that are used during coding, N is an integral power of 2, both N and K are positive integers, and N≥K.

The table selection module 402 is configured to select a target coding table from the plurality of candidate coding tables based on the target coding scheme, where the plurality of candidate coding tables are pre-stored in the sending apparatus.

The coding module 403 is configured to code the K information bits based on the target coding table to obtain a target coding sequence.

In this embodiment of this application, the target coding table may be used to store a generation matrix, or configured to store a simplified matrix, or configured to store a mapping relationship that is between candidate to-be-coded data and a candidate coding sequence and that corresponds to the target coding scheme. It may be understood that a manner in which the sending apparatus codes the K information bits based on the target coding table to obtain the target coding sequence varies with content of the target coding table. For detailed content, refer to the embodiment corresponding to FIG. 3.

In this embodiment of this application, after determining the target coding scheme, the sending apparatus further needs to send the target coding scheme to the receiving apparatus by using a sending module 404, so that the receiving apparatus performs decoding based on the target coding scheme. For detailed content about sending the target coding scheme to the receiving apparatus by the sending apparatus, refer to the embodiment corresponding to FIG. 3.

As shown in FIG. 6, the receiving apparatus 500 may include a receiving module 501, a determining module 502, an exhaustion module 503, and a selection module 504.

The receiving module 501 is configured to receive a target coding scheme, where the target coding scheme is used to indicate a quantity K of information bits and a mother code length N that are used during coding, N is an integral power of 2, both N and K are positive integers, and N>K.

The determining module 502 is configured to determine locations of the information bits in the target coding scheme based on a target information bit index table, where the target information bit index table is used to store the locations of the K information bits and locations of N−K fixed bits.

The exhaustion module 503 is configured to determine 2^{K} possible decoding results in an exhaustive manner based on the target coding scheme and the locations of the information bits, where each of the 2^{K} possible decoding results includes N bits.

The selection module 504 is configured to select an optimal possible decoding result from the 2^{K} possible decoding results as a decoding result of the polar coding.

It should be noted that for content that is not mentioned and specific implementations of function units in the embodiment in FIG. 6, refer to the embodiment in FIG. 3. Details are not described herein again.

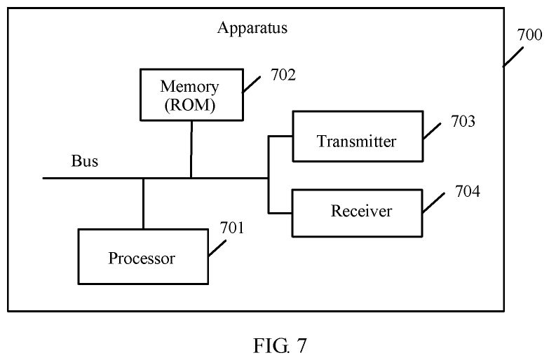

Based on a same inventive concept, an embodiment of the present application further provides an apparatus (as shown in FIG. 7). The apparatus is configured to implement the method described in the foregoing embodiment in FIG. 3 or FIG. 5. As shown in FIG. 7, the apparatus 700 includes: a transmitter 703, a receiver 704, a memory 702, and a processor 701 coupled to the memory 702 (there may be one or more processors 701, and one processor is used as an example in FIG. 7). The transmitter 703, the receiver 704, the memory 702, and the processor 701 may be connected to each other by using a bus or in another manner (connection by using a bus is used as an example in FIG. 7). The transmitter 703 is configured to send data to the outside, and the receiver 704 is configured to receive data from the outside. The memory 702 is configured to store program code, and the processor 701 is configured to invoke and run the program code stored in the memory 702.

When a hardware circuit or a logic circuit is used for implementation, the memory may be integrated with the processor.

When the apparatus 700 is a sending apparatus, the program code stored in the memory 702 is specifically used to implement a function of the sending apparatus in the embodiment in FIG. 3. Specifically, the processor 701 is configured to invoke the program code stored in the storage 702, to perform the following steps:

selecting, by the processor 701, a target coding scheme from a plurality of candidate coding schemes, where the target coding scheme is used to indicate a quantity K of information bits and a mother code length N that are used during coding, N is an integral power of 2, both N and K are positive integers, and N≥K;

selecting, by the processor 701, a target coding table from a plurality of candidate coding tables based on the target coding scheme, where the plurality of candidate coding tables are pre-stored in the sending apparatus; and

coding, by the processor 701, the K information bits based on the target coding table to obtain a target coding sequence.

In this embodiment of this application, the target coding table is used to store a target matrix. The target matrix may be implemented in the following two manners:

In a first manner, the target matrix may be a generation matrix. The generation matrix is an N×N matrix obtained through calculation based on G_{N}=F^{⊗n}, where G_{N} is the generation matrix, F^{⊗n} is F raised to a Kronecker power, and F^{⊗n}=F⊗F^{⊗(n-1)}.

In a second manner, the target matrix may be a simplified matrix. The simplified matrix is a matrix obtained by deleting a to-be-deleted row in a generation matrix based on a target information bit index table, and the generation matrix is an N×N matrix obtained through calculation based on G_{N}=F^{⊗n}, where G_{N} is the generation matrix, F^{⊗n} is F raised to a Kronecker power, F^{⊗n}=F⊗F^{⊗(n-1)}, the target information bit index table is used to indicate locations of the K information bits and locations of N−K fixed bits, the generation matrix includes K reserved rows and N−K to-be-deleted rows, locations of the K reserved rows correspond to the locations of the K information bits, and locations of the N−K to-be-deleted rows correspond to the locations of the N−K fixed bits.

In this embodiment of this application, the target coding table is used to store a one-to-one mapping relationship between 2^{K} pieces of candidate to-be-coded data and 2^{K} candidate coding sequences. The following describes three different implementations separately:

In a first manner, the 2^{K} candidate coding sequences are 2^{K} coding sequences obtained by respectively coding the 2^{K} pieces of candidate to-be-coded data based on the target coding scheme by using a polar channel coding method.

In a second manner, the 2^{K} candidate coding sequences are 2^{K} coding sequences obtained by respectively coding the 2^{K} pieces of candidate to-be-coded data based on the target coding scheme by using a polar channel coding method, and further performing puncturing processing on the coded data.

In a third manner, the 2^{K} candidate coding sequences are 2^{K} coding sequences obtained by respectively coding the 2^{K} pieces of candidate to-be-coded data based on the target coding scheme by using a polar channel coding method, and further performing repetition processing on the coded data.

In this embodiment of this application, a manner in which the processor 701 codes the K information bits based on the target coding table to obtain the target coding sequence varies with content of the target coding table. Details are provided below.

When the target coding table is used to store the generation matrix, the processor 701 extends the K information bits to N to-be-coded bits based on a target information bit index table, where the N to-be-coded bits include the K information bits and N−K fixed bits, and the target information bit index table is used to indicate locations of the K information bits and locations of the N−K fixed bits. The sending apparatus multiplies the N to-be-coded bits by the N×N generation matrix to obtain the target coding sequence.

When the target coding table is used to store the generation matrix, the processor 701 simplifies the N×N target matrix into a K×N simplified matrix based on a target information bit index table, where the target information bit index table is used to indicate locations of the K information bits and locations of N−K fixed bits, the generation matrix includes K reserved rows and N−K to-be-deleted rows, locations of the K reserved rows correspond to the locations of the K information bits, and locations of the N−K to-be-deleted rows correspond to the locations of the N−K fixed bits. The sending apparatus multiplies the K information bits by the K×N simplified matrix to obtain the target coding sequence.

When the target coding table is used to store the simplified matrix, the processor 701 multiplies the K information bits by a K×N simplified matrix to obtain the target coding sequence.

When the target coding table is used to store the one-to-one mapping relationship between the 2^{K} pieces of candidate to-be-coded data and the 2^{K} candidate coding sequences, the processor 701 queries the target coding table based on the K information bits, to select the target coding sequence from the candidate coding sequences, where the K information bits belong to the candidate to-be-coded data.

In this embodiment of this application, after determining the target coding scheme, the sending apparatus further needs to send the target coding scheme to the receiving apparatus by using the transmitter 703, so that the receiving apparatus performs decoding based on the target coding scheme. The transmitter 703 may send the target coding scheme in the following two embodiments:

In one embodiment, if a quantity of the candidate coding schemes is greater than a preset threshold, the transmitter 703 sends the target coding scheme to the receiving apparatus, so that the receiving apparatus performs decoding based on the target coding scheme, where the target coding scheme belongs to the candidate coding schemes.

In another embodiment, if a quantity of the candidate coding schemes is less than or equal to a preset threshold, the transmitter 703 sends a target index to the receiving apparatus, so that the receiving apparatus determines the target coding scheme based on the target index, and performs decoding based on the target coding scheme, where the target index belongs to candidate indexes, and there is a one-to-one correspondence between the candidate indexes and the candidate coding schemes.

It should be noted that when the apparatus 700 is a sending apparatus, for execution steps of the processor 701 and other technical features related to the processor 701, refer to related content about the sending apparatus in the method embodiment in FIG. 3. Details are not described herein again.

When the apparatus 700 is a receiving apparatus, the program code stored in the memory 702 is specifically used to implement a function of the receiving apparatus in the embodiment in FIG. 5. Specifically, the processor 701 is configured to invoke the program code stored in the storage 702, to perform the following steps:

receiving, by the processor 701, a target coding scheme, where the target coding scheme is used to indicate a mother code length N and a quantity K of information bits that are used during coding, N is an integral power of 2, both N and K are positive integers, and N≥K;

determining, by the processor 701, locations of the information bits in the target coding scheme based on a target information bit index table, where the target information bit index table is used to store the locations of the K information bits and locations of N−K fixed bits;

determining, by the processor 701, 2^{K} possible decoding results in an exhaustive manner based on the target coding scheme and the locations of the information bits, where each of the 2^{K} possible decoding results includes N bits; and

selecting, by the processor 701, an optimal possible decoding result from the 2^{K} possible decoding results as a decoding result of the polar coding.

In this embodiment of this application, the receiver 704 may receive the target coding scheme in the following two manners:

when a quantity of candidate coding schemes is greater than a preset threshold, determining, by the receiver 704, the target coding scheme by receiving the target coding scheme, where the target coding scheme belongs to the candidate coding schemes; or

when a quantity of candidate coding schemes is less than or equal to a preset threshold, selecting, by the receiver 704, the target coding scheme from the candidate coding schemes by receiving a target index, where the target index belongs to candidate indexes, and there is a one-to-one correspondence between the candidate indexes and the candidate coding schemes.

In this embodiment of this application, the processor 701 selects, based on a maximum likelihood method, an optimal possible decoding result from the 2^{K} possible decoding results as the decoding result of the polar coding.

It should be noted that when the apparatus 700 is a receiving apparatus, for execution steps of the processor 701 and other technical features related to the processor 701, refer to related content about the receiving apparatus in the method embodiment in FIG. 5. Details are not described herein again.

In addition, an embodiment of the present application further provides a communications system, and the communications system includes a sending apparatus and a receiving apparatus. When the sending apparatus performs coding by using the polar coding method in FIG. 3, the receiving apparatus may perform decoding by using a conventional decoding method, such as a successive cancellation (SC) algorithm, a belief propagation (BP) algorithm, an algorithm improved based on the SC algorithm, or an algorithm improved based on the BP algorithm, or may perform decoding by using the polar decoding method shown in FIG. 5. When the receiving apparatus performs decoding by using the polar decoding method shown in FIG. 5, the sending apparatus may perform coding by using a conventional polar coding method, or may perform coding by using the polar coding method shown in FIG. 3.

In this embodiment of this application, the sending apparatus can select the target coding scheme from the plurality of candidate coding schemes, select the target coding table from the plurality of candidate coding tables based on the target coding scheme, and code the K information bits based on the target coding table to obtain the target coding sequence, and does not need to calculate the generation matrix in real time, thereby reducing channel coding complexity, and avoiding consumption of a lot of computing time and computing resources. Therefore, a requirement of an application scenario that requires a low latency and a simple hardware system can be met.

All or some of the foregoing embodiments may be implemented by using software, hardware, firmware, or any combination thereof. When software is used to implement the embodiments, the embodiments may be implemented completely or partially in a form of a computer program product. The computer program product includes one or more computer instructions. When the computer instructions are loaded and executed on the computer, the procedures or functions according to the embodiments of the present application are all or partially generated. The computer may be a general-purpose computer, a dedicated computer, a computer network, or another programmable apparatus. The computer instructions may be stored in a computer readable storage medium or may be transmitted from a computer readable storage medium to another computer readable storage medium. For example, the computer instructions may be transmitted from a website, computer, server, or data center to another web site, computer, server, or data center in a wired (for example, a coaxial cable, an optical fiber, or a digital subscriber line (DSL)) or wireless (for example, infrared, radio, microwave, or the like) manner. The computer readable storage medium may be any usable medium accessible by a computer, or a data storage device, such as a server or a data center, integrating one or more usable media. The usable medium may be a magnetic medium (for example, a floppy disk, a hard disk, or a magnetic tape), an optical medium (for example, a DVD), a semiconductor medium (for example, a solid state disk (SSD)), or the like.

It should be understood that in the several embodiments provided in this application, the disclosed system, device and method may be implemented in other manners without departing from the scope of this application. For example, the described embodiments are merely examples. For example, the module or unit division is merely logical function division and may be other division in an actual implementation. For example, a plurality of units or components may be combined or integrated into another system, or some features may be ignored or not performed. The units described as separate parts may or may not be physically separate, and parts displayed as units may or may not be physical units, may be located in one position, or may be distributed on a plurality of network units. Some or all of the modules may be selected based on actual needs to achieve the objectives of the solutions of the embodiments. A person of ordinary skill in the art may understand and implement the embodiments of this application without creative efforts.

In addition, the schematic diagrams illustrating the system, device, method and different embodiments may be combined or integrated with other systems, modules, technologies or methods without departing from the scope of this application. In addition, the displayed or discussed mutual couplings or direct couplings or communication connections may be implemented by using some interfaces. The indirect couplings or communication connections between the apparatuses or units may be implemented in electronic, mechanical, or other forms.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

1. A method of polar channel coding, comprising:
selecting, by a sending apparatus, a target coding scheme from a plurality of candidate coding schemes, wherein the target coding scheme is used to indicate a quantity K of information bits and a mother code length N that are used during coding, N is an integral power of 2, both N and K are positive integers, and N≥K;
selecting, by the sending apparatus, a target coding table from a plurality of candidate coding tables based on the target coding scheme, wherein the plurality of candidate coding tables are pre-stored in the sending apparatus; and
coding, by the sending apparatus, the K information bits based on the target coding table to obtain a target coding sequence.

2. The method according to claim 1, wherein
the target coding table is used to store a target matrix, and
coding the K information bits based on the target coding table to obtain the target coding sequence comprises:
coding, by the sending apparatus, the K information bits based on the target matrix to obtain the target coding sequence.

3. The method according to claim 2, wherein
the target matrix is a generation matrix, and the generation matrix is an N×N matrix obtained through calculation based on G_{N}=F^{⊗n}, wherein G_{N} is the generation matrix, F^{⊗n} is F raised to a Kronecker power, and F^{⊗n}=F⊗F^{⊗(n-1)}; and
coding the K information bits based on the target matrix comprises:
extending, by the sending apparatus, the K information bits to N to-be-coded bits based on a target information bit index table, wherein the N to-be-coded bits comprise the K information bits and N−K fixed bits, and the target information bit index table is used to indicate locations of the K information bits and locations of the N−K fixed bits; and
multiplying, by the sending apparatus, the N to-be-coded bits by the N×N generation matrix to obtain the target coding sequence.

4. The method according to claim 2, wherein
the target matrix is a generation matrix, and the generation matrix is an N×N matrix obtained through calculation based on G_{N}=F^{⊗n}, wherein G_{N} is the generation matrix, F^{⊗n} is F raised to a Kronecker power, and F^{⊗n}=F⊗F^{⊗(n-1)}; and
coding the K information bits based on the target matrix comprises:
simplifying, by the sending apparatus, the N×N target matrix into a K×N simplified matrix based on a target information bit index table, wherein the target information bit index table is used to indicate locations of the K information bits and locations of N−K fixed bits, the generation matrix comprises K reserved rows and N−K to-be-deleted rows, locations of the K reserved rows correspond to the locations of the K information bits, and locations of the N−K to-be-deleted rows correspond to the locations of the N−K fixed bits; and
multiplying, by the sending apparatus, the K information bits by the K×N simplified matrix to obtain the target coding sequence.

5. The method according to claim 2, wherein
the target matrix is a K×N simplified matrix, the simplified matrix is a matrix obtained by simplifying a generation matrix based on a target information bit index table, and the generation matrix is an N×N matrix obtained through calculation based on G_{N}=F^{⊗n}, wherein G_{N} is the generation matrix, F^{⊗n} is F raised to a Kronecker power, F^{⊗n}=F⊗F^{⊗(n-1)}, the target information bit index table is used to indicate locations of the K information bits and locations of N−K fixed bits, the generation matrix comprises K reserved rows and N−K to-be-deleted rows, locations of the K reserved rows correspond to the locations of the K information bits, and locations of the N−K to-be-deleted rows correspond to the locations of the N−K fixed bits; and
coding the K information bits based on the target matrix comprises:
multiplying, by the sending apparatus, the K information bits by the K×N simplified matrix to obtain the target coding sequence.

6. The method according to claim 1, wherein
the target coding table is used to store a one-to-one mapping relationship between 2^{K} pieces of candidate to-be-coded data and 2^{K} candidate coding sequences; and
coding the K information bits based on the target coding table to obtain the target coding sequence comprises:
querying, by the sending apparatus, the target coding table based on the K information bits to select the target coding sequence from the candidate coding sequences, wherein the K information bits belong to the candidate to-be-coded data.

7. The method according to claim 6, wherein the 2^{K} candidate coding sequences are 2^{K} coding sequences obtained by respectively coding the 2^{K} pieces of candidate to-be-coded data based on the target coding scheme.

8. The method according to claim 6, wherein the 2^{K} candidate coding sequences are 2^{K} coding sequences obtained by respectively coding the 2^{K} pieces of candidate to-be-coded data based on the target coding scheme, and performing puncturing processing on the coded data.

9. The method according to claim 6, wherein the 2^{K} candidate coding sequences are 2^{K} coding sequences obtained by respectively coding the 2^{K} pieces of candidate to-be-coded data based on the target coding scheme, and performing repetition processing on the coded data.

10. The method according to claim 1, further comprising:
when a quantity of the candidate coding schemes is greater than a preset threshold, sending, by the sending apparatus, the target coding scheme to a receiving apparatus, so that the receiving apparatus performs decoding based on the target coding scheme, wherein the target coding scheme belongs to the candidate coding scheme; and
when a quantity of the candidate coding schemes is less than or equal to a preset threshold, sending, by the sending apparatus, a target index to a receiving apparatus, so that the receiving apparatus determines the target coding scheme based on the target index, and performs decoding based on the target coding scheme, wherein the target index belongs to candidate indexes, and there is a one-to-one correspondence between the candidate indexes and the candidate coding schemes.

11. A sending apparatus, comprising:
a processor and a memory coupled to the processor, wherein the memory is configured to store program code, and the processor is configured to execute the program code stored in the memory to perform:
selecting a target coding scheme from a plurality of candidate coding schemes, wherein the target coding scheme is used to indicate a quantity K of information bits and a mother code length N that are used during coding, N is an integral power of 2, both N and K are positive integers, and N≥K;
selecting a target coding table from a plurality of candidate coding tables based on the target coding scheme, wherein the plurality of candidate coding tables are pre-stored in the sending apparatus; and
coding the K information bits based on the target coding table to obtain a target coding sequence.

12. The sending apparatus according to claim 11, wherein
the target coding table is used to store a target matrix, and
coding the K information bits based on the target coding table comprises coding the K information bits based on the target matrix to obtain the target coding sequence.

13. The sending apparatus according to claim 12, wherein
the target matrix is a generation matrix, and the generation matrix is an N×N matrix obtained through calculation based on G_{N}=F^{⊗n}, wherein G_{N} is the generation matrix, F^{⊗n} is F raised to a Kronecker power, and F^{⊗n}=F⊗F^{⊗(n-1)}; and
coding the K information bits based on the target matrix comprises: extending the K information bits to N to-be-coded bits based on a target information bit index table, wherein the N to-be-coded bits comprise the K information bits and N−K fixed bits, and the target information bit index table is used to indicate locations of the K information bits and locations of the N−K fixed bits; and multiply the N to-be-coded bits by the N×N generation matrix to obtain the target coding sequence.

14. The sending apparatus according to claim 12, wherein
the target matrix is a generation matrix, and the generation matrix is an N×N matrix obtained through calculation based on G_{N}=F^{⊗n}, wherein G_{N} is the generation matrix, F^{⊗n} is F raised to a Kronecker power, and F^{⊗n}=F⊗F^{⊗(n-1)}; and
coding the K information bits based on the target matrix comprises: simplifying the N×N target matrix into a K×N simplified matrix based on a target information bit index table, wherein the target information bit index table is used to indicate locations of the K information bits and locations of N−K fixed bits, the generation matrix comprises K reserved rows and N−K to-be-deleted rows, locations of the K reserved rows correspond to the locations of the K information bits, and locations of the N−K to-be-deleted rows correspond to the locations of the N−K fixed bits; and multiply the K information bits by the K×N simplified matrix to obtain the target coding sequence.

15. The sending apparatus according to claim 12, wherein
the target matrix is a K×N simplified matrix, the simplified matrix is a matrix obtained by simplifying a generation matrix based on a target information bit index table, and the generation matrix is an N×N matrix obtained through calculation based on G_{N}=F^{⊗n}, wherein G_{N} is the generation matrix, F^{⊗n} is F raised to a Kronecker power, F^{⊗n}=F⊗F^{⊗(n-1)}, the target information bit index table is used to indicate locations of the K information bits and locations of N−K fixed bits, the generation matrix comprises K reserved rows and N−K to-be-deleted rows, locations of the K reserved rows correspond to the locations of the K information bits, and locations of the N−K to-be-deleted rows correspond to the locations of the N−K fixed bits; and
coding the K information bits based on the target matrix comprises: multiplying the K information bits by the K×N simplified matrix to obtain the target coding sequence.

16. The sending apparatus according to claim 11, wherein
the target coding table is used to store a one-to-one mapping relationship between 2^{K} pieces of candidate to-be-coded data and 2^{K} candidate coding sequences; and
coding the K information bits based on the target coding table comprises: querying the target coding table based on the K information bits, to select the target coding sequence from the candidate coding sequences, wherein the K information bits belong to the candidate to-be-coded data.

17. The sending apparatus according to claim 16, wherein the 2^{K} candidate coding sequences are 2^{K} coding sequences obtained by respectively coding the 2^{K} pieces of candidate to-be-coded data based on the target coding scheme.

18. The sending apparatus according to claim 16, wherein the 2^{K} candidate coding sequences are 2^{K} coding sequences obtained by respectively coding the 2^{K} pieces of candidate to-be-coded data based on the target coding scheme, and performing puncturing processing on the coded data.

19. The sending apparatus according to claim 16, wherein the 2^{K} candidate coding sequences are 2^{K} coding sequences obtained by respectively coding the 2^{K} pieces of candidate to-be-coded data based on the target coding scheme, and performing repetition processing on the coded data.

20. The apparatus according to claim 11, further comprising: a transmitter configured to perform:
when a quantity of the candidate coding schemes is greater than a preset threshold, sending the target coding scheme to a receiving apparatus, so that the receiving apparatus performs decoding based on the target coding scheme, wherein the target coding scheme belongs to the candidate coding scheme; and
when a quantity of the candidate coding schemes is less than or equal to a preset threshold, sending a target index to a receiving apparatus, so that the receiving apparatus determines the target coding scheme based on the target index, and performs decoding based on the target coding scheme, wherein the target index belongs to candidate indexes, and there is a one-to-one correspondence between the candidate indexes and the candidate coding schemes.
